(19) United States
(12) Patent Application Publication
(10) Pub. No.: US 2025/0248278 A1
(43) Pub. Date: Jul. 31, 2025

(54) DISPLAY DEVICE AND METHOD OF MANUFACTURING THE SAME

(71) Applicant: LG Display Co., Ltd., Seoul (KR)

(72) Inventors: Hyunsuk LEE, Paju-si (KR); Hyesook KIM, Paju-si (KR); SangWook LEE, Paju-si (KR); Hyoung-Su KIM, Paju-si (KR)

(73) Assignee: LG Display Co., Ltd., Seoul (KR)

(21) Appl. No.: 19/020,107

(22) Filed: Jan. 14, 2025

(30) Foreign Application Priority Data
Jan. 30, 2024 (KR) 10-2024-0013632

(51) Int. Cl. H10K 59/80; H10K 59/12; H10K 59/124; H10K 59/126; H10K 59/131; H10K 71/60; H10K 102/00

(52) U.S. Cl. CPC H10K 59/873; H10K 59/1201; H10K 59/124; H10K 59/126; H10K 59/131; H10K 71/60; H10K 2102/351

(57) ABSTRACT

A display device may include a display area, a non-display area, a circuit unit disposed on a substrate and disposed in the non-display area, a protective layer disposed on the circuit unit, an overcoat layer on the protective layer, a common electrode extending from the display area to the non-display area and disposed on the overcoat layer, an inorganic encapsulation layer extending from the display area to the non-display area and disposed on an upper portion and a side of the common electrode, a first protrusion protruding from the substrate, located further outside the common electrode, and having a first eaves, a second protrusion protruding from the substrate, located between the first protrusion and the display area, and having a second eaves, and a first separation inorganic layer disposed on the first protrusion, including the same material as the inorganic encapsulation layer, and separated from the inorganic encapsulation layer.

### CROSS REFERENCE TO RELATED APPLICATIONS

This application claims priority from Korean Patent Application No. 10-2024-0013632, filed on Jan. 30, 2024, the entire contents of which are incorporated herein by reference for all purposes as if fully set forth herein.

### BACKGROUND

### 1. Technical Field

Example embodiments of the present disclosure relate to a display device and a method of manufacturing the same.

### 2. Description of the Related Art

As the information society develops, there is increasing a demand for a display device for displaying images in various forms, and in recent years, there have been used various display devices such as liquid crystal display devices and organic light emitting display devices.

A display panel of a display device may include a display area where an image is displayed and a non-display area where the image is not displayed. For various reasons, there is an increasing need to reduce a size of the non-display area (also referred to as a “bezel”) of the display panel. However, various structures, circuits, and lines may be placed on the bezel of the display panel, so that it may be not easy to reduce the bezel of the display panel.

In addition, the bezel of the display panel may be an area with high probability of moisture or oxygen penetration. Therefore, if the bezel size is reduced, the possibility of moisture or oxygen penetration may increase accordingly.

The description of the related art should not be assumed to be prior art merely because it is mentioned in or associated with this section. The description of the related art includes information that describes one or more aspects of the subject technology, and the description in this section does not limit the invention.

### SUMMARY

Example embodiments of the present disclosure may provide a display device having a structure of narrow bezel and robust reliability (or high reliability robustness), and a method of manufacturing the same.

Example embodiments of the present disclosure may provide a display device with a structure advantageous for implementing the narrow bezel, and a method of manufacturing the same.

Example embodiments of the present disclosure may provide a display device with a structure capable of preventing cracks from spreading in an encapsulation layer within the display panel, and a method of manufacturing the same.

Example embodiments of the present disclosure may provide a display device with a structure capable of preventing a penetration of external substances such as moisture or oxygen, and a method of manufacturing the same.

Example embodiments of the present disclosure may provide a display device with a structure capable of preventing the external substances introduced inside from diffusing into a display area, and a method of manufacturing the same.

Example embodiments of the present disclosure may provide a display device with a structure capable of preventing image abnormalities caused by external substances introduced inside, and a method of manufacturing the same.

A display device according to example embodiments of the present disclosure may include a substrate, a display area in which a plurality of subpixels are disposed, a non-display area outside the display area, a circuit unit disposed on the substrate and disposed in the non-display area, a protective layer disposed on the circuit unit, an overcoat layer on the protective layer, a common electrode extending from the display area to the non-display area and disposed on the overcoat layer, an inorganic encapsulation layer extending from the display area to the non-display area and disposed on an upper portion and a side of the common electrode, a first protrusion protruding from the substrate, located further outside the common electrode, and having a first eaves, a second protrusion protruding from the substrate, located between the first protrusion and the display area, and having a second eaves, and a first separation inorganic layer disposed on the first protrusion, including the same material as the inorganic encapsulation layer, and separated from the inorganic encapsulation layer.

The inorganic encapsulation layer may be disconnected around the first protrusion, and may be not disconnected around the second protrusion.

A first thickness of the inorganic encapsulation layer around the first protrusion may be smaller than a second thickness of the inorganic encapsulation layer around the second protrusion.

The first eaves may have a larger size than the second eaves.

A method of manufacturing a display device according to example embodiments of the present disclosure may include a base step of forming a first bottom metal on a substrate in a first undercut structure area, forming a second bottom metal on the substrate in a second undercut structure area, forming a protective layer on the first bottom metal and the second bottom metal, and forming an overcoat layer on the protective layer, and a heterogeneous protrusion forming step of forming a first protrusion inside a first trench of the overcoat layer in the first undercut structure area, and forming a second protrusion inside a second trench of the overcoat layer in the second undercut structure area.

The first protrusion may include a first base metal formed by reducing the first lower metal, a first bottom insulating layer located on the first base metal, having a rear surface of a larger area than an upper surface of the first base metal, and including the same material as the protective layer, and a first top insulating layer located on the first bottom insulating layer and including the same material as the overcoat layer.

The second protrusion may include a second base metal corresponding to the second lower metal, a second bottom insulating layer located on the second base metal and including the same material as the protective layer, and a second top insulating layer located on the second bottom insulating layer, having a rear surface of a larger area than an upper surface of the second bottom insulating layer, and including the same material as the overcoat layer.

The substrate may be divided into a display area in which an image is displayed and a non-display area outside the display area. The first undercut structure area and the second undercut structure area may be included in the non-display area, and the first undercut structure area may be located farther from the display area than the second undercut structure area.

According to example embodiments of the present disclosure, there may be provided a display device having a structure for narrow bezel and reliability robustness, and a method of manufacturing the same.

According to example embodiments of the present disclosure, there may be provided a display device with a structure advantageous for implementing the narrow bezel, and a method of manufacturing the same.

According to example embodiments of the present disclosure, there may be provided a display device with a structure capable of preventing cracks from spreading in an encapsulation layer within the display panel, and a method of manufacturing the same.

According to example embodiments of the present disclosure, there may be provided a display device with a structure capable of preventing a penetration of external substances such as moisture or oxygen, and a method of manufacturing the same.

According to example embodiments of the present disclosure, there may be provided a display device with a structure capable of preventing the external substances introduced inside from diffusing into a display area, and a method of manufacturing the same.

According to example embodiments of the present disclosure, there may be provided a display device with a structure capable of preventing image abnormalities caused by external substances introduced inside, and a method of manufacturing the same.

According to example embodiments of the present disclosure, there may be possible to reduce the weight of the display device by having an extremely narrow bezel structure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a system configuration diagram of a display device according to example embodiments of the present disclosure.

FIG. 2 illustrates a display panel according to example embodiments of the present disclosure.

FIG. 3 illustrates an example of a system implementation of a display device according to example embodiments of the present disclosure.

FIG. 4 is a cross-sectional view of a display panel according to example embodiments of the present disclosure.

FIG. 5 illustrates a shadow phenomenon of an inorganic encapsulation layer of a display panel according to example embodiments of the present disclosure.

FIG. 6 is a diagram to explain an image abnormality of a display panel according to example embodiments of the present disclosure.

FIG. 7 is a cross-sectional view of a display panel having a structure for narrow bezel and reliability robustness according to example embodiments of the present disclosure.

FIG. 8 is a detailed cross-sectional view of a first undercut structure area in a display panel with a structure for narrow bezel and reliability robustness according to example embodiments of the present disclosure.

FIG. 9 is a detailed cross-sectional view of a second undercut structure area in a display panel with a structure for narrow bezel and reliability robustness according to example embodiments of the present disclosure.

FIG. 10 illustrates a circuit unit in a display panel according to example embodiments of the present disclosure in more detail.

FIGS. 11A to 11E illustrate a first undercut process in a display panel according to example embodiments of the present disclosure.

FIGS. 12A to 12H illustrate a second undercut process in a display panel according to example embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure. Further, the present disclosure is defined by the scope of claims and their equivalents.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply, for example, to a separate circuit, component or structure, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

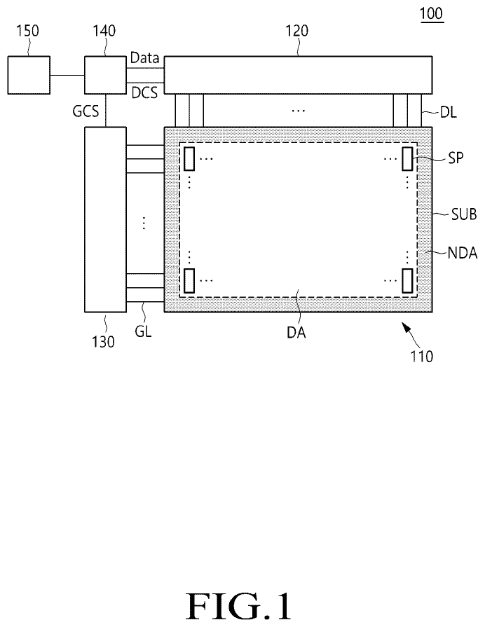

FIG. 1 is a system configuration diagram of a display device 100 according to example embodiments of the present disclosure.

Referring to FIG. 1, a display device 100 according to example embodiments of the present disclosure may include a display panel 110 and a driving circuit for driving the display panel 110.

The driving circuit may include a data driving circuit 120 and a gate driving circuit 130, and may further include a controller 140 for controlling the data driving circuit 120 and the gate driving circuit 130.

The display panel 110 may include a substrate SUB and signal lines such as a plurality of data lines DL and a plurality of gate lines GL disposed on the substrate SUB. The display panel 110 may include a plurality of subpixels SP connected to a plurality of data lines DL and a plurality of gate lines GL.

The display panel 110 may include a display area DA where an image is displayed and a non-display area NDA where an image is not displayed. In the display panel 110, a plurality of subpixels SP for displaying an image may be disposed in the display area DA. In the non-display area NDA, the driving circuits 120, 130 and 140 may be electrically connected or the driving circuits 120, 130, and 140 may be mounted, and there may be disposed a pad portion to which an integrated circuit or printed circuit may be connected.

The data driving circuit 120 is a circuit for driving a plurality of data lines DL, and may output data signals to the plurality of data lines DL.

The gate driving circuit 130 is a circuit for driving a plurality of gate lines GL, and may output gate signals to the plurality of gate lines GL.

The controller 140 may supply a data control signal DCS to the data driving circuit 120 to control the operation timing of the data driving circuit 120, and may supply a gate control signal GCS to the gate driving circuit 130 to control the operation timing of the gate driving circuit 130.

The controller 140 may start scanning according to the timing implemented in each frame, may convert the input image data input from the outside to fit the data signal format used in the data driving circuit 120, and may supply converted image data Data to the data driving circuit 120 and control data driving at an appropriate time according to the scan.

The controller 140 may receive various timing signals including a vertical synchronization signal VSYNC, a horizontal synchronization signal HSYNC, an input data enable signal DE, a clock signal CLK in addition to the input image data from the outside (e.g., the host system 150).

In order to control the data driving circuit 120 and the gate driving circuit 130, the controller 140 may receive timing signals such as a vertical synchronization signal VSYNC, a horizontal synchronization signal HSYNC, an input data enable signal DE, and a clock signal CLK, and generate various control signals DCS and GCS and output to the data driving circuit 120 and the gate driving circuit 130.

For example, the controller 140 may output various gate control signals GCS including a gate start pulse GSP, a gate shift clock GSC, and a gate output enable signal GOE in order to control the gate driving circuit 130.

In addition, in order to control the data driving circuit 120, the controller 140 may output various data control signals DCS including uses a source start pulse SS), a source sampling clock SSC, and a source output enable signal SOE.

The controller 140 may be implemented as a separate component from the data driving circuit 120, or may be integrated with the data driving circuit 120 and implemented as an integrated circuit.

The data driving circuit 120 may receive image data Data from the controller 140 and supply a data voltage to the plurality of data lines DL, thereby driving the plurality of data lines DL. Here, the data driving circuit 120 may be also referred to as a source driving circuit.

The data driving circuit 120 may include one or more source driver integrated circuits SDIC.

Each source driver integrated circuit SDIC may include a shift register, a latch circuit, a digital to analog converter DAC, an output buffer. In some cases, each source driver integrated circuit SDIC may further include an analog to digital converter ADC.

For example, each source driver integrated circuit SDIC may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The gate driving circuit 130 may output a gate signal of a turn-on level voltage or a gate signal of a turn-off level voltage according to the control of the controller 140. The gate driving circuit 130 may sequentially drive a plurality of gate lines GL by sequentially supplying a gate signal with a turn-on level voltage to the plurality of gate lines GL.

The gate driving circuit 130 may be connected to the display panel 110 using a tape automated bonding (TAB) method, or may be connected to a bonding pad of the display panel 110 using a chip-on-glass (COG) or chip-on-panel (COP) method, or may be connected to the display panel 110 according to a chip-on-film (COF) method. Alternatively, the gate driving circuit 130 may be a gate-in-panel (GIP) type, and may be formed in the non-display area NDA of the display panel 110. The gate driving circuit 130 may be disposed on or connected to the substrate SUB. That is, if the gate driving circuit 130 is of the GIP type, it may be disposed in the non-display area NDA of the substrate SUB. The gate driving circuit 130 may be connected to the substrate SUB in the case of a chip-on-glass (COG) type, chip-on-film (COF) type, etc.

Meanwhile, at least one of the data driving circuit 120 and the gate driving circuit 130 may be disposed in the display area DA.

For example, the gate driving circuit 130 may be disposed in the display area DA. In this case, the gate driving circuit 130 may be disposed over the entire display area DA or only in a portion of the display area DA. The gate driving circuit 130 may be disposed not to overlap the subpixels SP, or may be disposed to partially or entirely overlap the subpixels SP.

As another example, the data driving circuit 120 may be disposed in the display area DA. In this case, the data driving circuit 120 may be disposed throughout the entire display area DA or only in a portion of the display area DA. The data driving circuit 120 may be disposed not to overlap the subpixels SP, or may be disposed to partially or entirely overlap the subpixels SP.

When a specific gate line GL is selected by the gate driving circuit 130, the data driving circuit 120 may convert the image data Data received from the controller 140 into an analog data voltage, and may supply to the plurality of data lines DL.

The data driving circuit 120 may be connected to one side (e.g., the upper or lower side) of the display panel 110. Depending on the driving method or panel design method, the data driving circuit 120 may be connected to both sides (e.g., upper and lower sides) of the display panel 110, or may be connected to two or more of the four sides of the display panel 110.

The gate driving circuit 130 may be connected to one side (e.g., left or right) of the display panel 110. Depending on the driving method or panel design method, the gate driving circuit 130 may be connected to both sides (e.g., left and right) of the display panel 110, or may be connected to two or more of the four sides of the display panel 110.

The controller 140 may be a timing controller used in typical display technology, or may be a control device capable of further performing other control functions including a timing controller, or may be a control device different from the timing controller, or may be a control device other than a timing controller, or may be a circuit within the control device. The controller 140 may be implemented with various circuits or electronic components, such as an integrated circuit (IC), a field programmable gate array (FPGA), an application specific integrated circuit (ASIC), or a processor.

The controller 140 may be mounted on a printed circuit board, a flexible printed circuit, etc., and may be electrically connected to the data driving circuit 120 and the gate driving circuit 130 through a printed circuit board, a flexible printed circuit.

The controller 140 may transmit and receive signals with the data driving circuit 120 according to one or more predetermined interfaces. For example, the interface may include a low voltage differential signaling (LVDS) interface, an embedded clock point-point interface (EPI) interface, or a serial peripheral interface (SPI).

The controller 140 may include a storage medium such as one or more registers.

The display device 100 according to example embodiments of the present disclosure may be a display device in which the display panel 110 cannot emit light on its own. For example, the display device 100 according to example embodiments of the present disclosure may be a liquid crystal display device including a backlight unit.

Alternatively, the display device 100 according to example embodiments of the present disclosure may be a self-luminous display device in which the display panel 110 can emit light on its own. For example, the display device 100 according to example embodiments of the present disclosure may be one of the display devices including an organic light emitting diode (OLED) display device, a quantum dot display device, and a micro light emitting diode (Micro LED) display device.

If the display device 100 according to example embodiments of the present disclosure is an organic light emitting diode display device, each subpixel SP may include an organic light emitting diode which emits light by itself as a light emitting device. If the display device 100 according to example embodiments of the present disclosure is a quantum dot display device, each subpixel SP may include a light emitting element made of quantum dots, which are semiconductor crystals which emit light on their own. If the display device 100 according to example embodiments of the present disclosure is a micro light emitting diode display device, each subpixel SP may include a micro light emitting diodes, which emit light on their own and are made based on inorganic materials, as a light emitting device.

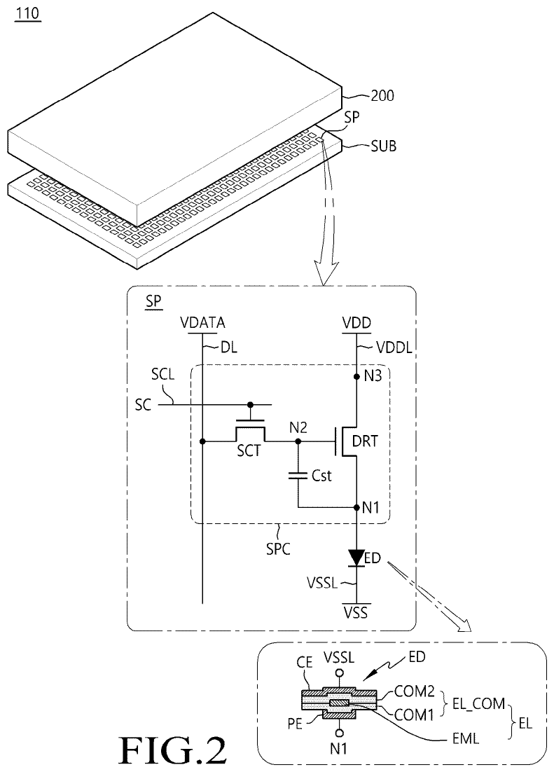

FIG. 2 illustrates a display panel 110 according to example embodiments of the present disclosure.

Referring to FIG. 2, the display panel 110 may include a substrate SUB disposed in a plurality of subpixels SP and an encapsulation layer 200 on the substrate SUB. Here, the encapsulation layer 200 may also be referred to as an encapsulation substrate or an encapsulation portion.

Referring to FIG. 2, when the display device 100 according to example embodiments of the present disclosure is a self-luminous display device, each of the plurality of subpixels SP disposed on the substrate SUB may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DRT for driving the light emitting device ED, and a scan transistor SCT which is turned on or off depending on the scan signal SC.

The driving transistor DRT may supply driving current to the light emitting device ED.

The scan transistor SCT may be configured to control the electrical state of a corresponding node (e.g., second node, N2) in the subpixel circuit SPC or to control the state or operation of the driving transistor DRT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common driving voltage including a first driving voltage VDD and a second driving voltage VSS may be applied to the subpixel SP in order to drive the subpixel SP.

The light emitting device ED may include a pixel electrode PE, an intermediate layer EL, and a common electrode CE. The intermediate layer EL may be disposed between the pixel electrode PE and the common electrode CE.

In the case that the light emitting device ED is an organic light emitting device, the intermediate layer EL may include the emission layer EML and a common intermediate layer EL_COM. The common intermediate layer EL_COM may include a first common intermediate layer COM1 and a second common intermediate layer COM2. The first common intermediate layer COM1 may be disposed between the pixel electrode PE and the emission layer EML, and may include at least one layer (e.g., an organic layer). The second common intermediate layer COM2 may be disposed between the emission layer EML and the common electrode CE, and may include at least one layer (e.g., an organic layer).

For example, the emission layer EML may be disposed in each of the plurality of subpixels SP, or in another example, may be commonly disposed in the plurality of subpixels SP. The common intermediate layer EL_COM may be commonly disposed across the plurality of subpixels SP.

The emission layer EML may be disposed in each emission area, and the common intermediate layer EL_COM may be commonly disposed across a plurality of emission areas and non-emission areas.

The pixel electrode PE may be an electrode disposed in each subpixel SP, and the common electrode CE may be an electrode commonly disposed in a plurality of subpixels SP.

For example, the pixel electrode PE may be an anode and the common electrode CE may be a cathode. For another example, the pixel electrode PE may be a cathode and the common electrode CE may be an anode. Hereinafter, it will be exemplified an example in which the pixel electrode PE is an anode and the common electrode CE is a cathode.

For example, the first common intermediate layer COM1 of the common intermediate layer EL_COM may include a hole injection layer HIL and a hole transport layer HTL, and the second common intermediate layer COM2 of the common intermediate layer EL_COM may include an electron transport layer ETL and an electron injection layer EIL.

The hole injection layer may inject holes from the pixel electrode PE to the hole transport layer, the hole transport layer may transport holes to the emission EML, the electron injection layer may inject electrons from the common electrode CE to the electron transport layer, and the electron transport layer may transport electrons to the emission layer EML.

For example, the common electrode CE may be electrically connected to a second driving voltage line VSSL. A second driving voltage VSS, which is a type of common driving voltage, may be applied to the common electrode CE through the second driving voltage line VSSL. The pixel electrode PE may be electrically connected directly or indirectly (via another transistor) to the first node N1 of the driving transistor DRT of each subpixel SP. In the present disclosure, “second common driving voltage VSS” may also be referred to as “base voltage VSS,” and “second common driving voltage line VSSL” may be referred to as “base voltage line VSSL.”

Each light emitting device ED may be composed of an overlapping portion of a pixel electrode PE, an emission layer EML in an intermediate layer EL, and a common electrode CE. A predetermined emission area may be formed by each light emitting device ED. For example, the emission area of each light emitting device ED may include an overlapping area of the pixel electrode PE, the emission layer EML in the intermediate layer EL, and the common electrode CE.

For example, the light emitting device ED may be an organic light emitting diode (OLED), an inorganic light emitting diode, or a quantum dot light emitting device. For example, in the case that the light emitting device ED is an organic light emitting diode OLED, the intermediate layer EL in the light emitting device ED may include an organic film containing an organic material.

The driving transistor DRT may be a driving transistor for supplying driving current to the light emitting device ED. The driving transistor DRT may be connected between a first driving voltage line VDDL and the light emitting device ED.

The driving transistor DRT may include a first node N1, a second node N2, and a third node N3. The first node N1 may be electrically connected to the light emitting device ED, the second node N2 may be applied with the data signal VDATA, and the third node N3 may be applied with a first common driving voltage VDD from the first common driving voltage line VDDL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DRT.

The scan transistor SCT included in the subpixel circuit SPC illustrated in FIG. 2 may be a switching transistor for transmitting a data signal VDATA, which is an image signal, to the second node N2 which is the gate node of the driving transistor DRT.

The scan transistor SCT may be controlled on-off by the scan signal SC which is a gate signal applied through the scan line SCL as a type of gate line GL, and may control the electrical connection between the second node N2 of the driving transistor DRT and the data line DL. The drain electrode or source electrode of the scan transistor SCT may be electrically connected to the data line DL, and the source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the first node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The storage capacitor Cst may be an external capacitor intentionally designed outside the driving transistor DRT rather than a parasitic capacitor (e.g., Cgs, Cgd) as an internal capacitor which may exist between the first node N1 and the second node N2 of the driving transistor DRT.

Each of the driving transistor DRT and the scan transistor SCT may be an n-type transistor or a p-type transistor.

The display panel 110 may have a top emission structure or a bottom emission structure.

In the case that the display panel 110 has a top emission structure, at least a portion of the subpixel circuit SPC may overlap with at least a portion of the light emitting device ED in a vertical direction. Accordingly, there may be increased the area of the emission area the aperture ratio.

If the display panel 110 has a bottom emission structure, the subpixel circuit SPC may not overlap with the light emitting device ED in the vertical direction.

As shown in FIG. 2, the subpixel circuit SPC may have 2T-1C structure including two transistors (e.g., the driving transistor DRT and the scan transistor SCT) and one capacitor (e.g., the storage capacitor Cst). In some cases, the subpixel circuit SPC may further include one or more transistors or one or more capacitors.

Depending on the structure of the subpixel circuit SPC, there may vary the type and number of gate signal and/or gate lines supplied to the subpixel SP. In addition, depending on the structure of the subpixel circuit SPC, there may vary the type and number of common driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the substrate SUB of the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

The display device 100 according to an embodiment of the present disclosure may have an extremely narrow bezel structure in which the non-display area NDA of the display panel 110 is very small.

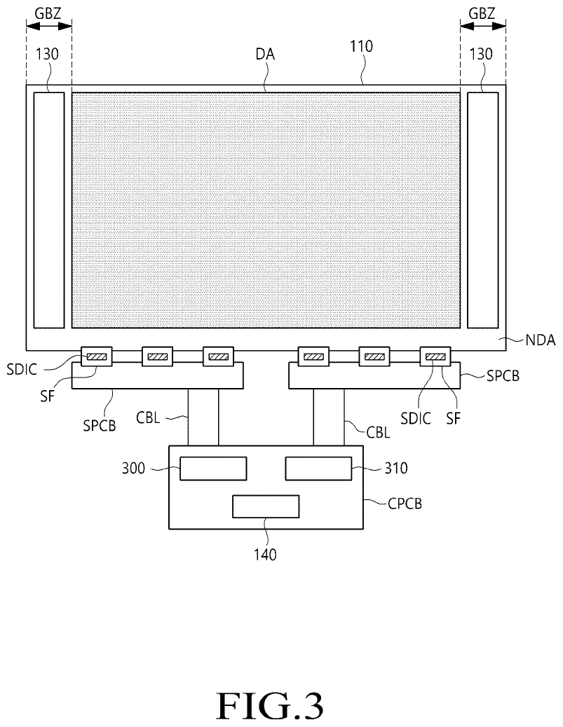

FIG. 3 illustrates an example of a system implementation of a display device 100 according to example embodiments of the present disclosure.

Referring to FIG. 3, the display panel 110 may include a display area DA where an image is displayed and a non-display area NDA where an image is not displayed.

Referring to FIG. 3, in the case that the data driving circuit 120 includes one or more source driver integrated circuits SDIC and is implemented in a chip-on-film (COF) method, each source driver integrated circuit SDIC may be mounted on a circuit film SF connected to the non-display area NDA of the display panel 110.

Referring to FIG. 3, the gate driving circuit 130 may be implemented as a gate-in-panel (GIP) type. In this case, the gate driving circuit 130 may be formed in the non-display area NDA of the display panel 110. Unlike FIG. 3, the gate driving circuit 130 may be implemented as a chip-on-film (COF) type.

For circuit connection between one or more source driver integrated circuits SDIC and other devices, the display device 100 may include at least one source printed circuit board SPCB, and a control printed circuit board CPCB for mounting control components and various electrical devices.

A film SF on which a source driver integrated circuit SDIC is mounted may be connected to at least one source printed circuit board SPCB. That is, one side of the film SF on which the source driver integrated circuit SDIC is mounted may be electrically connected to the display panel 110 and the other side of the film SF may be electrically connected to the source printed circuit board SPCB.

The controller 140 and a power management integrated circuit PMIC 310 may be mounted on the control printed circuit board CPCB. The controller 140 may perform overall control functions related to driving the display panel 110 and control the operations of the data driving circuit 120 and the gate driving circuit 130. The power management integrated circuit 310 may supply various voltages or currents to the data driving circuit 120 and the gate driving circuit 130, or control various voltages or currents to be supplied.

At least one source printed circuit board SPCB and a control printed circuit board CPCB may be electrically connected through at least one connection cable CBL. Here, the connection cable CBL may be, for example, a flexible printed circuit FPC, a flexible flat cable FFC, etc.

At least one source printed circuit board SPCB and a control printed circuit board CPCB may be integrated and implemented as one printed circuit board.

The display device 100 according to example embodiments of the present disclosure may further include a level shifter 300 for adjusting the voltage level. For example, the level shifter 300 may be disposed on a control printed circuit board CPCB or a source printed circuit board SPCB.

In the display device 100 according to example embodiments of the present disclosure, the level shifter 300 may supply signals necessary for gate driving to the gate driving circuit 130. For example, the level shifter 300 may supply a plurality of clock signals (i.e., gate clock signals) to the gate driving circuit 130. Accordingly, the gate driving circuit 130 may generate a plurality of gate signals based on a plurality of gate clock signals input from the level shifter 300, and output the plurality of gate signals to a plurality of gate lines GL. Here, the plurality of gate lines GL may transmit a plurality of gate signals to the subpixels SP disposed in the display area DA of the substrate SUB.

Referring to FIG. 3, the non-display area NDA of the display panel 110 may include a gate bezel area GBZ where the gate driving circuit 130 and its related lines are disposed.

Referring to FIG. 3, there may be required to be disposed various lines necessary for the operation of the gate driving circuit 130 in the gate bezel area GBZ in addition to the gate driving circuit 130 of the GIP type. Here, various lines required for the operation of the gate driving circuit 130 may include a plurality of gate clock lines, at least one high level gate voltage line, and at least one low level gate voltage line.

Hereinafter, it will be described a structure of the gate bezel area GBZ of the display panel 110 according to example embodiments of the present disclosure.

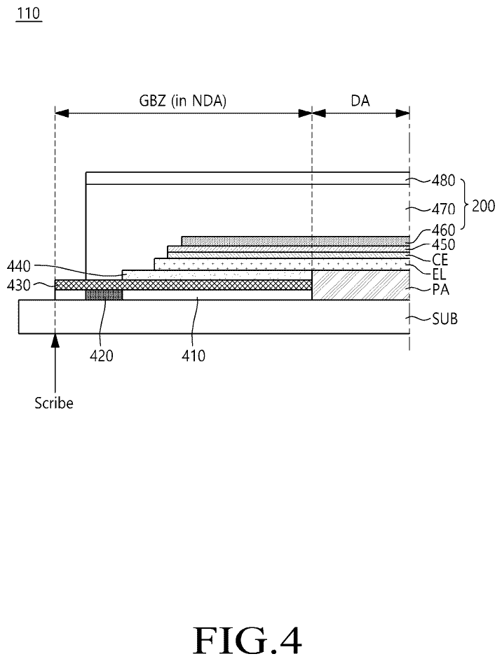

FIG. 4 is a cross-sectional view of a display panel 110 according to example embodiments of the present disclosure. However, the cross-sectional view of FIG. 4 illustrates a state before performing a scribing process during the manufacturing process of the display panel 110.

Referring to FIG. 4, the display panel 110 according to example embodiments of the present disclosure may include a substrate SUB, a circuit unit 410, an overcoat layer 430, a bank 440, an intermediate layer EL, a common electrode CE, and an inorganic encapsulation layer 460.

The circuit unit 410 may include a gate driving circuit 130 of the GIP type.

The circuit unit 410 may be disposed on the substrate SUB, and may be disposed in a gate bezel area GBZ within a non-display area NDA.

The overcoat layer 430 may be disposed on the circuit unit 410.

The bank 440 may be disposed on the overcoat layer 430.

The intermediate layer EL may be disposed on the bank 440 by extending from the display area DA to the non-display area NDA. The intermediate layer EL may overlap with at least a portion of the circuit unit 410 disposed in the gate bezel area GBZ within the non-display area NDA.

The common electrode CE may extend from the display area DA to the non-display area NDA, and may be disposed on the intermediate layer EL. The common electrode CE may overlap with at least a portion of the circuit unit 410 disposed in the gate bezel area GBZ within the non-display area NDA.

The inorganic encapsulation layer 460 may be an inorganic layer included in the encapsulation layer 200. The inorganic encapsulation layer 460 may extend from the display area DA to the non-display area NDA, and may be disposed on the common electrode CE. The inorganic encapsulation layer 460 may overlap with at least a portion of the circuit unit 410 disposed in the gate bezel area GBZ within the non-display area NDA. For example, the inorganic encapsulation layer 460 may include one or more of silicon nitride (SiNx), silicon oxide (SiOx), and silicon nitride oxide (SiON).

Referring to FIG. 4, the display panel 110 according to example embodiments of the present disclosure may further include an adhesive layer 470 and a metal encapsulation layer 480 on the adhesive layer 470. The encapsulation layer 200 may include an inorganic encapsulation layer 460, the adhesive layer 470, and the metal encapsulation layer 480.

Referring to FIG. 4, the display panel 110 according to example embodiments of the present disclosure may further include a ground line 420 disposed further outward from the circuit unit 410.

Referring to FIG. 4, the display panel 110 according to example embodiments of the present disclosure may further include a capping layer 450 on the common electrode CE. The capping layer 450 may be considered as a layer included in the encapsulation layer 200.

Referring to FIG. 4, in the display panel 110 according to example embodiments of the present disclosure, the pixel area PA in the display area DA may be an area where the subpixel SP is formed, and a plurality of signal lines, a plurality of transistors, a plurality of capacitors, a plurality of pixel electrodes may be disposed in the pixel area PA. In addition, various metal layers and various insulating layers may be disposed in the pixel area PA to arrange a plurality of signal lines, a plurality of transistors, a plurality of capacitors, and a plurality of pixel electrodes.

For example, a plurality of transistors including a driving transistor DRT and a scan transistor SCT, and a plurality of storage capacitors Cst may be disposed in the pixel area PA. In addition, a plurality of signal lines including a plurality of data lines DL, a plurality of gate lines GL, a plurality of first common driving voltage lines VDDL may be disposed in the pixel area PA.

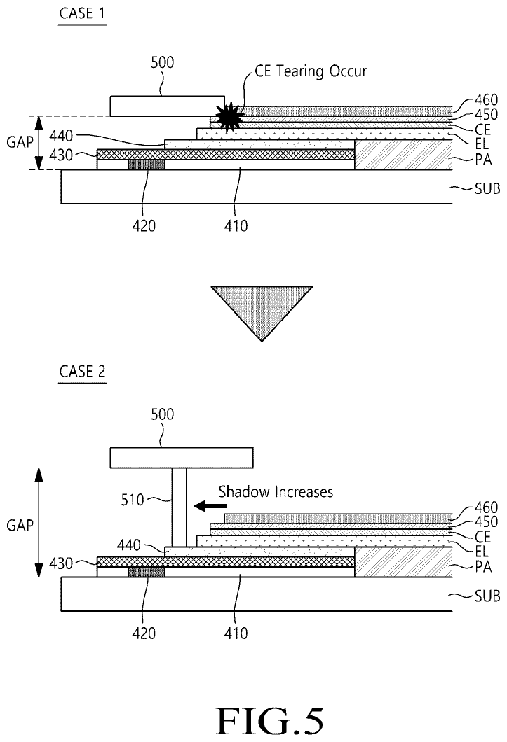

FIG. 5 is a diagram for explaining a shadow phenomenon of the inorganic encapsulation layer 460 of the display panel 110 according to example embodiments of the present disclosure.

Referring to FIG. 5, when depositing the inorganic encapsulation layer 460 in the manufacturing process of the display panel 110, as in Case 1, if a gap GAP between a deposition mask 500 and the substrate SUB is too small, there may occur an issue where the common electrode CE is torn off during or after the deposition process.

In order to prevent the issue of tearing of the common electrode CE, as in case 2, the deposition process of the inorganic encapsulation layer 460 may be performed by coating a floating metal embossing (FME) 510 on the back of the deposition mask 500 to widen the gap GAP between the deposition mask 500 and the substrate SUB.

The minimum gap GAP between the deposition mask 500 and the substrate SUB to prevent tearing of the common electrode CE may be greater than or equal to a threshold value determined for each type of display panel 110.

Referring to FIG. 5, when the deposition process of the inorganic encapsulation layer 460 is performed as in Case 2, the inorganic encapsulation layer 460 may be deposited extending further outward than the desired point due to the widened gap GAP between the deposition mask 500 and the substrate SUB.

In embodiments of the present disclosure, the phenomenon in which the inorganic encapsulation layer 460 extends further outward than the desired point may be referred to as a “shadow phenomenon of the inorganic encapsulation layer 460.” In addition, a portion of the inorganic encapsulation layer 460 extending further outward than the desired point may be referred to as a “shadow.”

The bezel may become larger due to the shadow phenomenon of the inorganic encapsulation layer 460. That is, the shadow phenomenon of the inorganic encapsulation layer 460 may be a limiting factor in implementing a narrow bezel.

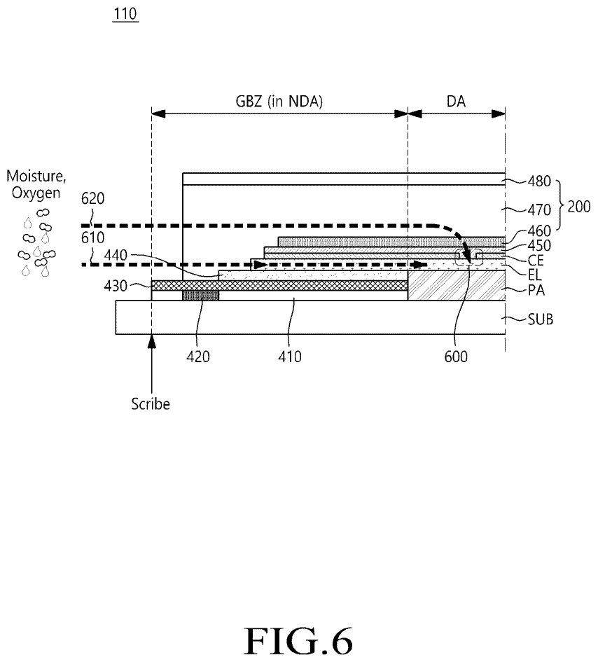

FIG. 6 is a diagram to explain an image abnormality of a display panel 110 according to example embodiments of the present disclosure.

Referring to FIG. 6, the inventors of the present application analyzed the image abnormality phenomenon of the display panel 110 and found the cause through numerous experiments and analysis. Accordingly, there has been found that when external substances (e.g., moisture, oxygen, etc.) flow into the display panel 110 and reach a certain point, an abnormal image phenomenon occurs.

Referring to FIG. 6, external substances (e.g., moisture, oxygen, etc.) present in the atmosphere may flow into the display panel 110 through the adhesive layer 470.

Referring to FIG. 6, external substances flowing into the display panel 110 may flow into the intermediate layer EL after reaching a point where the adhesive layer 470 and the intermediate layer EL contact each other. External substances introduced into the intermediate layer EL along a first movement path 610 may reach the display area DA. The movement path of these external substances may be referred to as a first movement path 610.

External substances introduced into the intermediate layer EL along the first movement path 610 may oxidize the common electrode CE in contact with the intermediate layer EL. This phenomenon may continue to spread to various points within the display area DA, and may be perceived with the naked eye of user.

Referring to FIG. 6, external substances introduced into the display panel 110 may reach a defective portion 600 of the common electrode CE along the adhesive layer 470. This movement path of external substances may be referred to as a second movement path 620.

External substances reaching the defective portion 600 of the common electrode CE along the second movement path 620 may oxidize the common electrode CE. This phenomenon may continue to spread to various points within the display area DA, and may be perceived with the naked eye.

The above-mentioned image abnormalities due to the inflow and internal movement of external substances may occur during the manufacturing process of the display panel 110, or may occur even after completing the manufacturing of the display panel 110.

Accordingly, the display panel 110 according to example embodiments of the present disclosure may have a structure for narrow bezel and reliability robustness in consideration of the shadow phenomenon and image abnormality phenomenon of the inorganic encapsulation layer 460. Hereinafter, it will be described a structure for narrow bezel and reliability robustness of the display panel 110 according to example embodiments of the present disclosure in detail.

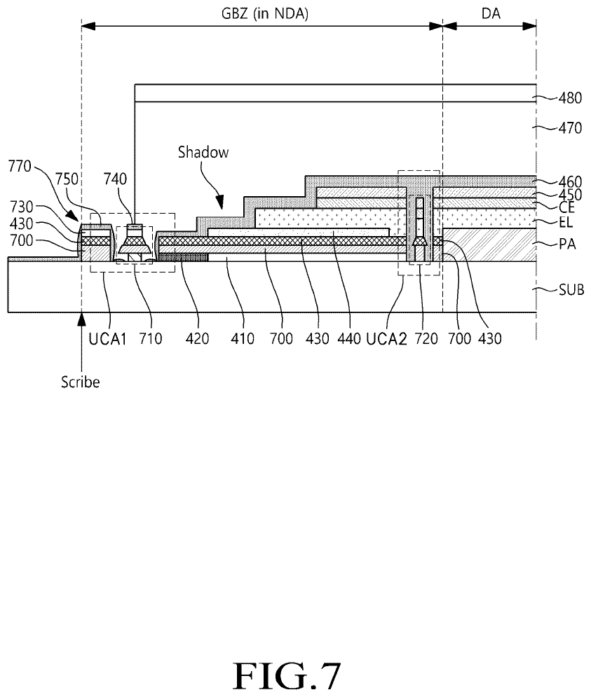

FIG. 7 is a cross-sectional view of a display panel 110 having a structure for narrow bezel and reliability robustness according to example embodiments of the present disclosure. However, hereinafter, there will be omitted the description of the same content as the cross-sectional view of FIG. 4 and the description will mainly focus on the content different from the cross-sectional view of FIG. 4.

Referring to FIG. 7, in the display panel 110 according to example embodiments of the present disclosure, the inorganic encapsulation layer 460 deposited according to the deposition process described in FIG. 5 may be extended in an outer area of the common electrode CE. The portion extending from the inorganic encapsulation layer 460 to the outer area of the common electrode CE (i.e., a portion of the inorganic encapsulation layer 460) may be referred to as a “shadow.”

Referring to FIG. 7, the display panel 110 according to example embodiments of the present disclosure may include a first undercut structure area UCA1 and a second undercut structure area UCA2 in order to prevent side effects caused by the shadow of the inorganic encapsulation layer 460 and prevent image abnormalities.

The side effects due to the shadow of the inorganic encapsulation layer 460 may include a bezel expansion due to the shadow of the inorganic encapsulation layer 460 and diffusion of moisture due to a crack in the shadow of the inorganic encapsulation layer 460. Here, the diffusion of moisture due to a crack in the shadow of the inorganic encapsulation layer 460 may mean that moisture penetrating due to cracks in the shadow of the inorganic encapsulation layer 460 spread or diffuse deeply to other areas.

Referring to FIG. 7, the first undercut structure area UCA1 may be an area where a first protrusion 710 is formed inside a first trench of the overcoat layer 430. Here, the first protrusion 710 may also be referred to as a first tip.

By using the first undercut structure area UCA1, there may be prevented the expansion of the bezel due to the shadow of the inorganic encapsulation layer 460, and there may be blocked the diffusion of moisture due to cracks in the shadow of the inorganic encapsulation layer 460.

Referring to FIG. 7, the second undercut structure area UCA2 may be an area where a second protrusion 720 is formed inside a second trench of the overcoat layer 430. Here, the second protrusion 720 may also be referred to as a second tip.

Due to the second undercut structure area UCA2, there may be prevented the external substances (e.g., moisture, oxygen, etc.), which flows into the common electrode CE from the non-display area NDA, from spreading into the common electrode CE in the display area DA.

Referring to FIG. 7, the display panel 110 according to example embodiments of the present disclosure may include a substrate SUB with a display area DA where a plurality of subpixels SP are disposed and a non-display area NDA outside the display area DA, a circuit unit 410 disposed on the substrate SUB and in the non-display area NDA, a protective layer 700 disposed on the circuit unit 410, an overcoat layer 430 on the protective layer 700, a common electrode CE extending from the display area DA to the non-display area NDA and disposed on the overcoat layer 430, and an inorganic encapsulation layer 460 extending from the display area DA to the non-display area NDA and disposed on an upper portion the and sides of the common electrode CE (in other words, disposed above the common electrode CE and on a side of the common electrode CE).

Referring to FIG. 7, the display panel 110 according to example embodiments of the present disclosure may further include a first protrusion 710 which protrudes from the substrate SUB, is located further outward from the common electrode CE, and has a first eaves EVS1, a second protrusion 720 which protrudes from the substrate SUB, is located between the first protrusion 710 and the display area DA, and has a second eaves EVS2.

Referring to FIG. 7, the display panel 110 according to example embodiments of the present disclosure may further include a first separation inorganic layer 740 disposed on the first protrusion 710, made of the same material as the inorganic encapsulation layer 460, and separated from the inorganic encapsulation layer 460.

In addition, the display panel 110 according to example embodiments of the present disclosure may further include a second separation inorganic layer 750 disposed on the outside of the first protrusion 710, made of the same material as the inorganic encapsulation layer 460, and separated from the first separation inorganic layer 740.

During the process of forming the first protrusion 710, a hill portion 770 may exist on the outside of the first protrusion 710. The hill portion 770 may have the same stacked structure as a portion located inside the first protrusion 710. That is, the hill portion 770 may include a protective layer 700, an overcoat layer 430, etc.

Due to the formation of the first protrusion 710, the inorganic encapsulation layer 460 may be broken or disconnected. That is, in the process of forming the first protrusion 710, the inorganic encapsulation layer 460 may be broken or disconnected on the inside and outside of the first protrusion 710 (in other words, around the first protrusion 710).

The inorganic encapsulation layer 460 may be broken or disconnected inside the first protrusion 710.

Inside the first protrusion 710, the inorganic encapsulation layer 460 extending from the display area DA, and the disconnected inorganic encapsulation layer 460 may remain on an upper portion of the first protrusion 710 (in other words, may remain on top of the first protrusion 710). The inorganic encapsulation layer 460 remaining on the first protrusion 710 may correspond to the first separation inorganic layer 740.

The inorganic encapsulation layer 460 may be also broken or disconnected on the outside of the first protrusion 710.

The first separation inorganic layer 740 and the disconnected inorganic encapsulation layer 460 on the outside of the first protrusion 710 may remain on an upper portion of the hill portion 770 located on the outside of the first protrusion 710. The inorganic encapsulation layer 460 remaining on the upper portion of the hill portion 770 outside the first protrusion 710 may correspond to the second separation inorganic layer 750.

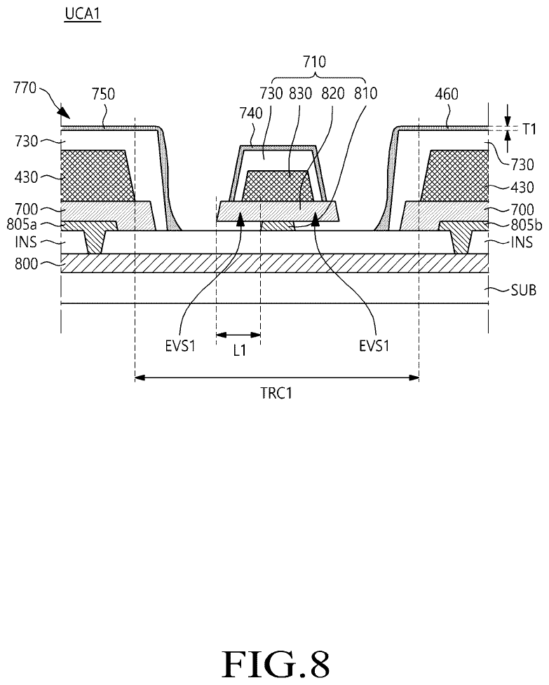

Referring to FIG. 7, in the process of forming the first protrusion 710, there may be formed a first trench (TRC1 in FIG. 8) of the material layer including the protective layer 700 and the overcoat layer 430.

The first protrusion 710 may be located inside the first trench (TRC1 in FIG. 8) of the material layer including the protective layer 700 and the overcoat layer 430.

The inorganic encapsulation layer 460 may be disposed in the outer area of the first trench TRC1. The inorganic encapsulation layer 460 disposed in the outer area of the first trench TRCI may correspond to the second separation inorganic layer 750.

Referring to FIG. 7, the inorganic encapsulation layer 460 may be broken or disconnected inside and outside the first protrusion 710, but the inorganic encapsulation layer 460 may be not broken or disconnected at and around the second protrusion 720.

That is, the inorganic encapsulation layer 460 may be disposed on the second protrusion 720, and may be seamlessly disposed in the outer and inner areas of a second trench TRC2 without a disconnection.

Since the inorganic encapsulation layer 460 near the first protrusion 710 corresponds to a shadow, it may have a thin first thickness. In comparison, the inorganic encapsulation layer 460 near the second protrusion 720 may have a second thickness that is relatively greater than the first thickness.

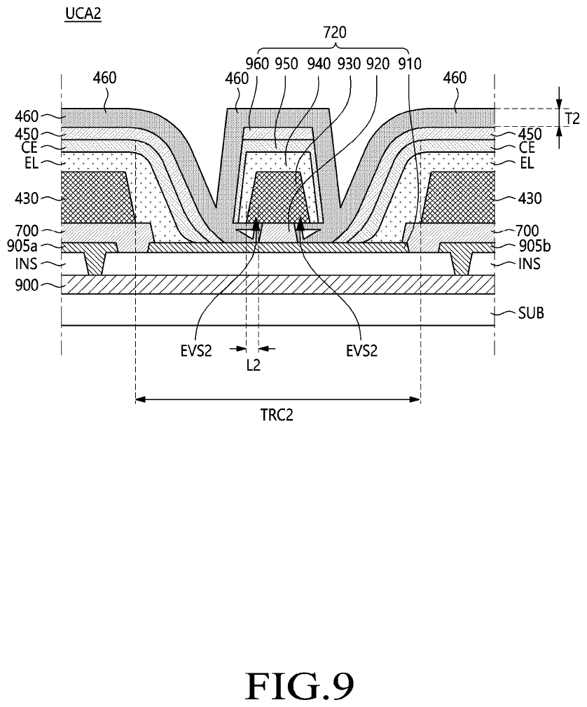

Referring to FIG. 7, in the process of forming the second protrusion 720, there may be formed a second trench (TRC2 in FIG. 9) of the material layer including the protective layer 700 and the overcoat layer 430.

The second protrusion 720 may be located inside the second trench (TRC2 in FIG. 9) of the material layer including the protective layer 700 and the overcoat layer 430.

Referring to FIG. 7, the first protrusion 710 may be located outside the circuit unit 410, and the second protrusion 720 may be located between the circuit unit 410 and the display area DA.

Referring to FIG. 7, a ground line 420 may be disposed between the first protrusion 710 and the circuit unit 410.

The inorganic encapsulation layer 460 may extend to the outer side of the ground line 420.

Referring to FIG. 7, the first protrusion 710 may further include an adhesive functional layer 730 on the overcoat layer 430 (in other words, as shown in FIG. 8, which will be described below, the first protrusion 710 may further include an adhesive functional layer 730 on a first top insulating layer 830 corresponding to the overcoat layer 430).

The adhesive functional layer 730 may include an adhesive material having a relatively high adhesive force (i.e., bonding force) with the inorganic encapsulation layer 460. Here, the adhesive material may be an adhesive material used in a display panel.

The adhesive functional layer 730 may be further disposed on the overcoat layer 430 located on the outside of the first protrusion 710. The adhesive functional layer 730 may be further disposed on the overcoat layer 430 located inside the first protrusion 710.

Hereinafter, it will be described the first undercut structure area UCA1 where the first protrusion 710 is located and the second undercut structure area UCA2 where the second protrusion 720 is located in more detail. First, it will be described a vertical structure of the first undercut structure area UCA1 where the first protrusion 710 is located with reference to FIG. 8.

FIG. 8 is a detailed cross-sectional view of a first undercut structure area UCA1 in a display panel 110 with a structure for narrow bezel and reliability robustness according to example embodiments of the present disclosure.

Referring to FIG. 8, the first protrusion 710 present in the first undercut structure area UCA1 may include a first base metal 810, a first bottom insulating layer 820 located on the first base metal 810 and having a rear surface with a larger area than an upper surface of the first base metal 810, and a first top insulating layer 830 on first bottom insulating layer 820.

Referring to FIG. 8, the first bottom insulating layer 820 may include the same material as the protective layer 700 (or be formed of the same material as the protective layer 700), and may be separated from the protective layer 700.

The first top insulating layer 830 may include the same material as the overcoat layer 430 (or be formed of the same material as the overcoat layer 430), and may be separated from the overcoat layer 430.

As described above, the first protrusion 710 may have a undercut structure in which the first base metal 810 located below the first bottom insulating layer 820 containing the same material as the protective layer 700 is depressed inward.

The first separation inorganic layer 740 on top of the first protrusion 710 (or on the upper of the first protrusion 710) may be a portion of the inorganic encapsulation layer 460 disconnected from the inorganic encapsulation layer 460 extending from the display area DA on the inside of the first protrusion 710.

The second separation inorganic layer 750 on the hill portion 770 on the outside of the first protrusion 710 may be a portion of the inorganic encapsulation layer 460 disconnected from the first separation inorganic layer 740 outside of the first protrusion 710

The inorganic encapsulation layer 460, the first separation inorganic layer 740, and the second separation inorganic layer 750 may be only separated from each other during the formation of the first protrusion 710, and may include the same inorganic material (or be formed of the same inorganic material).

Referring to FIG. 8, a first eaves EVS1 of the first protrusion 710 may include a portion of the first bottom insulating layer 820 extending further than the first base metal 810.

The first eaves EVS1 of the first protrusion 710 may have a first length L1. Here, the first length L1 of the first eaves EVS1 may correspond to the size of the first eaves EVS1. That is, if the first length L1 of the first eaves EVS1 is long, the size of the first eaves EVS1 may be large. If the first length Ll of the first eaves EVS1 is short, the size of the first eaves EVS1 may be small.

Referring to FIG. 8, the inorganic encapsulation layer 460 is disconnected or broken by the first eaves EVS1 of the first protrusion 710.

In the first undercut structure area UCA1, the inorganic encapsulation layer 460 may have a first thickness T1, and the first separation inorganic layer 740 may have a thickness equal to or less than the first thickness T1. The second separation inorganic layer 750 may have a thickness equal to or less than the thickness of the first separation inorganic layer 740.

Referring to FIG. 8, the first protrusion 710 may further include an adhesive functional layer 730 on the first top insulating layer 830.

The adhesive functional layer 730 and the inorganic encapsulation layer 460 may be disconnected by the first eaves EVS1 of the first protrusion 710.

Referring to FIG. 8, the display panel 110 according to example embodiments of the present disclosure may further include a base insulating layer INS between the substrate SUB and the first protrusion 710, and a first shield metal 800 located between the substrate SUB and the base insulating layer INS and overlapping with the first protrusion 710.

Referring to FIG. 8, the display panel 110 according to example embodiments of the present disclosure may further include a first outer metal pattern 805a located outside the first protrusion 710 and disposed between the base insulating layer INS and the protective layer 700, and a first inner metal pattern 805b located inside the first protrusion 710 and disposed between the base insulating layer INS and the protective layer 700.

The first outer metal pattern 805a may be connected to a portion of the first shield metal 800 through a hole in the base insulating layer INS, and the first inner metal pattern 805b may be connected to another portion of the first shield metal 800 through a hole in the base insulating layer INS.

A ground voltage may be applied to the first shield metal 800.

The first shield metal 800 may be part of the ground line 420, or may be a pattern electrically connected to the ground line 420.

Referring to FIG. 8, the first protrusion 710 may be considered as being located inside the first trench TRCI formed by removing the overcoat layer 430 and the protective layer 700.

Hereinafter, it will be described a vertical structure of the second undercut structure area UCA2 where the second protrusion 720 is located.

FIG. 9 is a detailed cross-sectional view of a second undercut structure area UCA2 in a display panel 110 with a structure for narrow bezel and reliability robustness structure according to example embodiments of the present disclosure.

Referring to FIG. 9, the second protrusion 720 may include a second base metal 910, a second bottom insulating layer 920 located on the second base metal 910 and having a rear surface of smaller area than an upper surface of the second base metal 910, a second top insulating layer 930 located on the second bottom insulating layer 920 and having a rear surface with a larger area than an upper surface of the second bottom insulating layer 920, an organic material layer 940 on the second top insulating layer 930, and a top metal 950 on organic material layer 940.

Referring to FIG. 9, the second bottom insulating layer 920 may include the same material as the protective layer 700 (or be formed of the same material as the protective layer 700) and may be separated from the protective layer 700, and the second top insulating layer 930 may include the same material as the overcoat layer 430 (or be formed of the same material as the overcoat layer 430) and may be separated from the overcoat layer 430.

The organic material layer 940 may include an organic material included in the intermediate layer EL and may be separated from the intermediate layer EL, and the top metal 950 may include the same metal as the common electrode CE (or be formed of the same metal as the common electrode CE) and may be separated from the common electrode CE.

Accordingly, the second protrusion 720 may have a structure in which the second bottom insulating layer 920 located below the second top insulating layer 930 containing the same material as the overcoat layer 430 is depressed inward.

The second eaves EVS2 may include a portion of the second top insulating layer 930 extending further outward than the second bottom insulating layer 920.

The second eaves EVS2 may further include an organic material layer 940 and a top metal 950 located on the side of the second top insulating layer 930.

The total length of the second eaves EVS2 may be the sum of a second length L2, which is a length of the extended portion of the second top insulating layer 930 extending further outward than the second bottom insulating layer 920, a thickness of the organic material layer 940, and a thickness of the top metal 950.

For example, the first length L1 of the first eaves EVS1 may be greater than the total length of the second eaves EVS2. Accordingly, the inorganic encapsulation layer 460 may easily break or may be disconnected around the first protrusion 710.

The second protrusion 720 may further include a separation capping layer 960 on the top metal 950.

In the process of forming the second protrusion 720, the separation capping layer 960 may be a layer separated from a capping layer 450. The separation capping layer 960 may include the same material as the capping layer 450 located around the second protrusion 720.

Referring to FIG. 9, the display panel 110 according to example embodiments of the present disclosure may further include a base insulating layer INS between the substrate SUB and the second protrusion 720, and a second shield metal 900 located between the substrate SUB and the base insulating layer INS and overlapping with the second protrusion 720 (or be formed of the same material as the capping layer 450 located around the second protrusion 720).

Referring to FIG. 9, the display panel 110 according to example embodiments of the present disclosure may further include a second outer metal pattern 905a located outside the second protrusion 720 and disposed between the base insulating layer INS and the protective layer 700, and a second inner metal pattern 905b located inside the second protrusion 720 and disposed between the base insulating layer INS and the protective layer 700.

The second outer metal pattern 905a may be connected to a portion of the second shield metal 900 through a hole in the base insulating layer INS, and the second inner metal pattern 905b may be connected to another portion of the second shield metal 900 through a hole in the base insulating layer INS.

The second protrusion 720 may be disposed in an area of the circuit unit 410 and the display area DA.

A signal output from the circuit unit 410 may be applied to the second shield metal 900.

The second shield metal 900 may electrically connect a signal line disposed in the display area DA and the circuit unit 410.

In the second undercut structure area UCA2, the inorganic encapsulation layer 460 may be not disconnected or cut off in and around the second protrusion 720.

In the second undercut structure area UCA2, the inorganic encapsulation layer 460 may have a second thickness T2. The second thickness T2 of the inorganic encapsulation layer 460 in the second undercut structure area UCA2 may be greater than the first thickness T1 of the inorganic encapsulation layer 460 in the first undercut structure area UCA1.

Referring to FIG. 9, the second protrusion 720 may be considered as being located inside the second trench TRC2 formed by removing the overcoat layer 430 and the protective layer 700. The second trench TRC2 may be a trench of the intermediate layer EL.

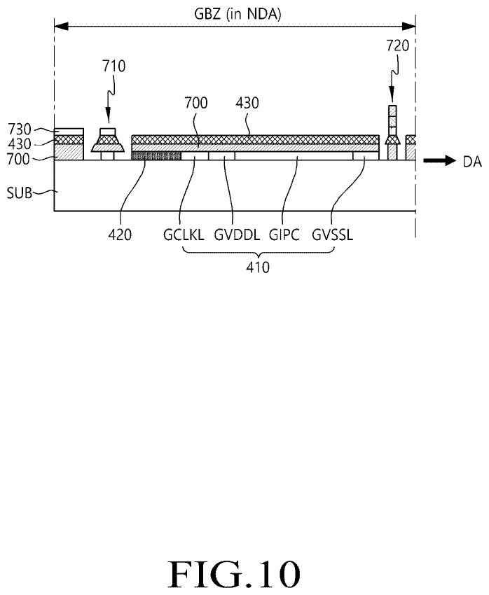

FIG. 10 illustrates circuit unit 410 in a display panel 110 according to example embodiments of the present disclosure in more detail.

Referring to FIG. 10, the circuit unit 410 may include a gate-in-panel circuit GIPC outputting a scan signal to a plurality of subpixels SP, a plurality of gate clock lines GCLKL disposed between the first protrusion 710 and the gate-in-panel circuit GIPC, a first gate voltage line GVDDL disposed between the plurality of gate clock lines GCLKL and the gate-in-panel circuit GIPC, and a second gate voltage line GVSSL disposed between the gate-in-panel circuit GIPC and the second protrusion 720.

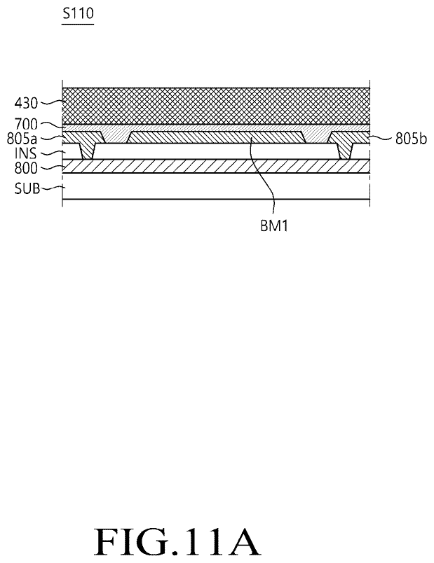

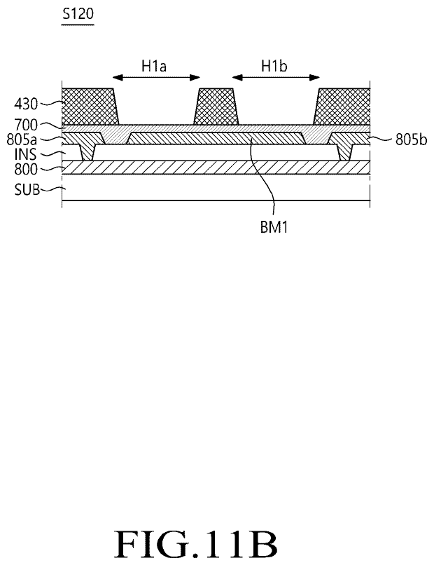

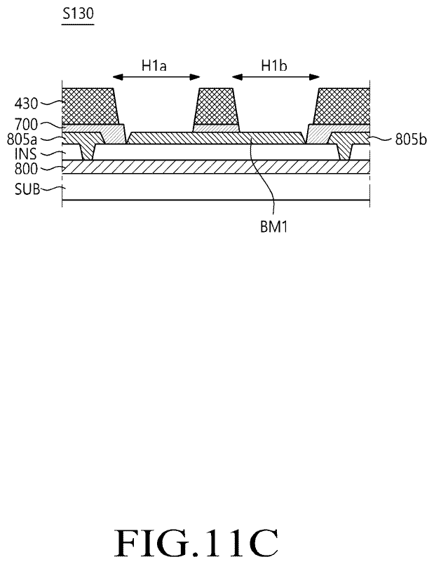

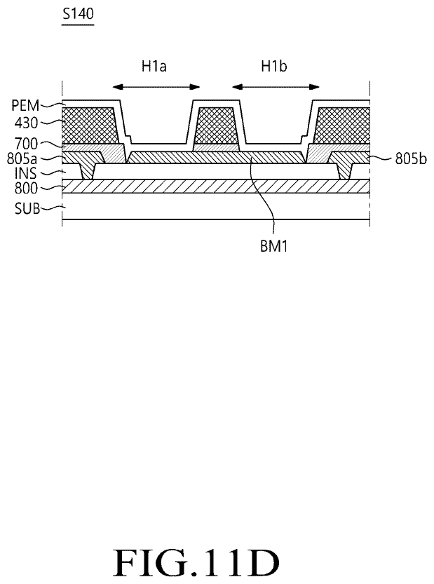

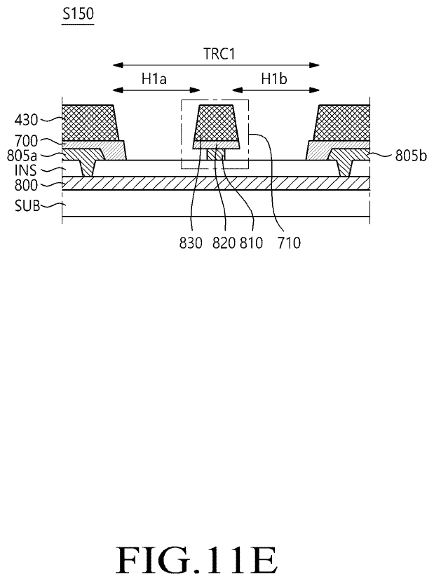

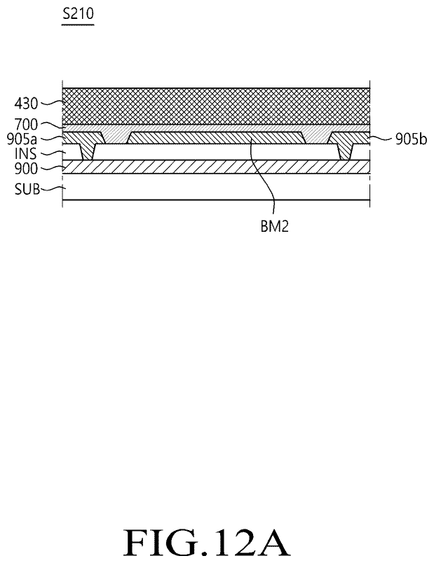

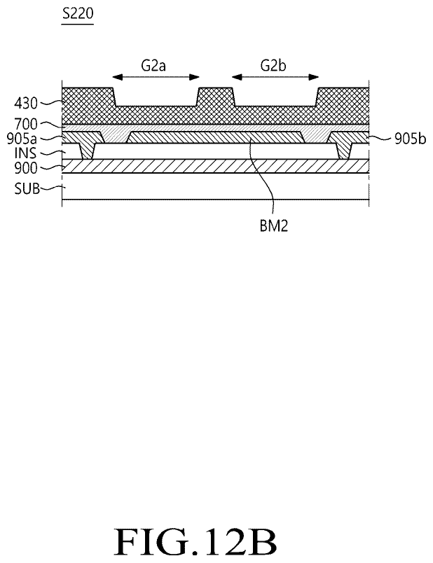

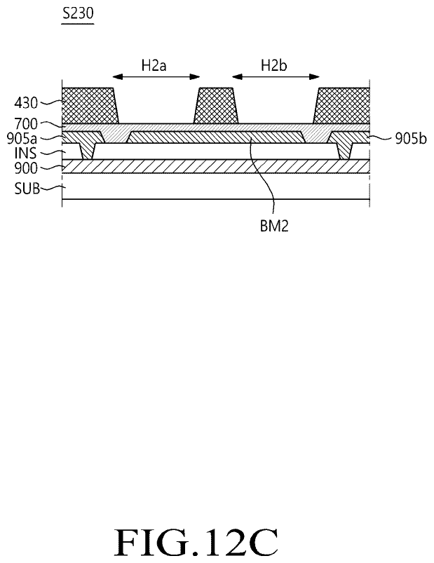

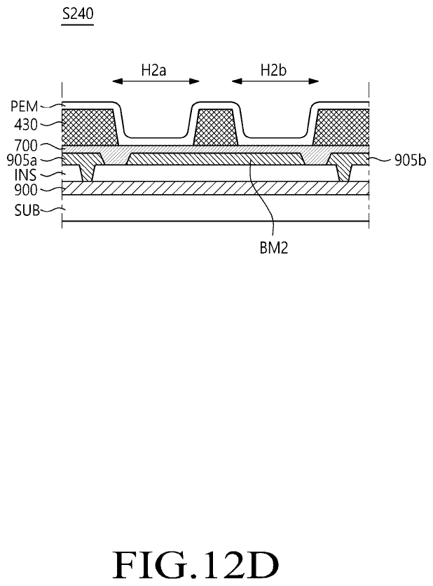

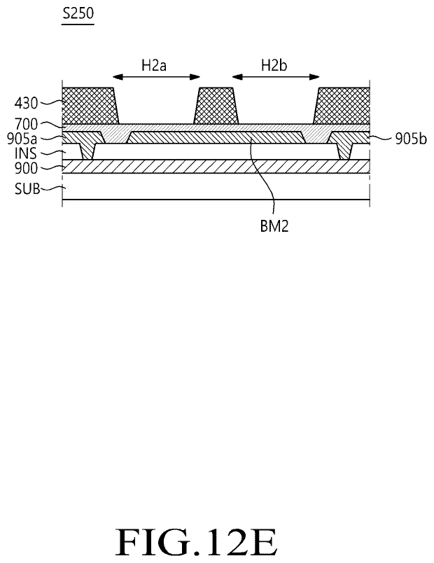

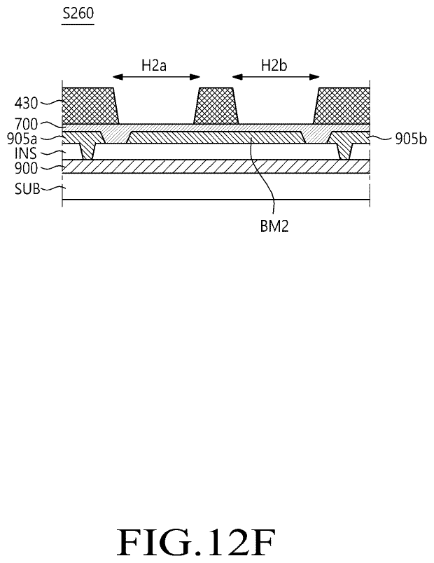

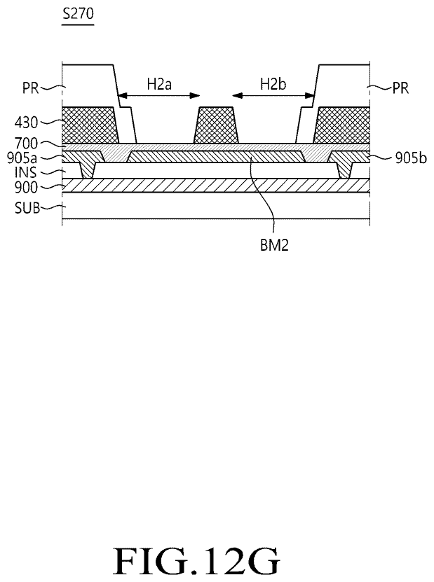

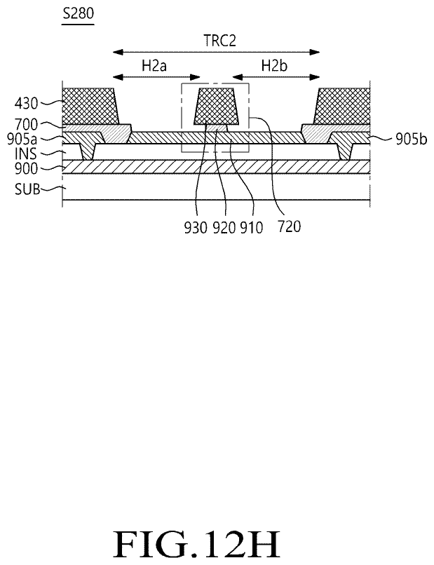

FIGS. 11A to 11E illustrate a first undercut process in a display panel 110 according to example embodiments of the present disclosure, and FIGS. 12A to 12H illustrate a second undercut process in a display panel 110 according to example embodiments of the present disclosure. However, in the following description, FIGS. 7 to 9 are also referred to.

FIGS. 11A to 11E illustrate processes of forming the first protrusion 710 in the first undercut structure area UCA1, and FIGS. 12A to 12H illustrate processes of forming the second protrusion 720 in the second undercut structure area UCA2.

Referring to FIGS. 11A to 11E and FIGS. 12A to 12H, a method of manufacturing a display device 100 according to example embodiments of the present disclosure may include a base step (S110, S210) and a heterogeneous protrusion forming step (S120˜S150, S220˜S280).

In the base step (S110, S210), a first lower metal BM1 may be formed on the substrate SUB in the first undercut structure area UCA1, a second lower metal BM2 may be formed on the substrate SUB in the second undercut structure area UCA2, a protective layer 700 may be formed on the first lower metal BM1 and the second lower metal BM2, and an overcoat layer 430 may be formed on the protective layer 700.

Hereinafter, it will be described in more detail a first stage (i.e., steps S110 and S210) corresponding to the base step.

In the base step (S110, S210), a first shield metal 800 may be formed on the substrate SUB in the first undercut structure area UCA1, and the second shield metal 900 may be formed on the substrate SUB in the second undercut structure area UCA2.

In addition, in the base step (S110, S210), an insulating layer INS may be formed on the first shield metal 800 and the second shield metal 900. For example, the insulating layer INS may include a buffer layer and a gate insulating layer.

In addition, in the base step (S110, S210), a first outer metal pattern 805a and a first inner metal pattern 805b may be formed on the insulating layer INS, and may be connected to one side and the other side of the first shield metal 800 through a hole in the insulating layer INS in the first undercut structure area UCA1.

Additionally, in the base step (S110, S210), a second outer metal pattern 905a and a second inner metal pattern 905b may be formed on the insulating layer INS, and may be connected to one side and the other side of the second shield metal 900 through a hole in the insulating layer INS in the second undercut structure area UCA2.

Furthermore, in the base step (S110, S210), a protective layer 700 may be formed on the first outer metal pattern 805a, the first inner metal pattern 805b, the second outer metal pattern 905a, and the second inner metal pattern 905b. Thereafter, an overcoat layer 430 may be formed on the protective layer 700.

In the heterogeneous protrusion forming steps (S120 to S150, S220 to S280), a first protrusion 710 may be formed inside a first trench TRCI of the overcoat layer 430 in a first undercut structure area UCA1, and a second protrusion 720 may be formed inside a second trench TRC2 of the overcoat layer 430 in a second undercut structure area UCA2.

The first protrusion 710 may include a first base metal 810 formed by reducing the first lower metal BM1.

The first protrusion 710 may include a first bottom insulating layer 820 located on the first base metal 810, having a rear surface with a larger area than an upper surface of the first base metal 810, and including the same material as the protective layer 700 (or being formed of the same material as the protective layer 700), and a first top insulating layer 830 located on the first bottom insulating layer 820 and including the same material as the overcoat layer 430 (or being formed of the same material as the overcoat layer 430).

The second protrusion 720 may include a second base metal 910 corresponding to the second lower metal BM2, a second bottom insulating layer 920 located on the second base metal 910 and including the same material as the protective layer 700 (or being formed of the same material as the protective layer 700), and a second top insulating layer 930 located on the second bottom insulating layer 920, having a rear surface of larger area than an upper surface of the second bottom insulating layer 920, and including the same material as the overcoat layer 430 (or being formed of the same material as the overcoat layer 430).

The substrate SUB may be divided into a display area DA where an image is displayed and a non-display area NDA outside the display area DA.

The first undercut structure area UCA1 and the second undercut structure area UCA2 may be included in the non-displayed area NDA, and the first undercut structure area UCA1 may be located farther from the display area DA than the second undercut structure area UCA2.

The base step may be a first step (S110, S210), and the heterogeneous protrusion forming step that proceed after the first step (S110, S210) may include the second step (S120, S220), the third step (S130, S230), the fourth step (S140, S240), the fifth step (S150, S250), the sixth step (S260), the seventh step (S270), and the eighth step (S280).

In the second step (S120, S220), by using a halftone photo mask, a first hole H1a and a second hole H1b may be formed in the overcoat layer 430 on the first lower metal BM1, and a third groove G2a and a fourth groove G2b may be formed in the overcoat layer 430 on the second lower metal BM2.

In the third step (S130, 230), the protective layer 700 may be wet-etched and the overcoat layer 430 may be ashed. In the step S130, in the first undercut structure area UCA1, the protective layer 700 overlapping the first hole H1a and the second hole H1b may be etched. In the step S230, in the second undercut structure area UCA2, the third groove G2a and the fourth groove G2b of the overcoat layer 430 may be penetrated to form the third hole H2a and the fourth hole H2b in the overcoat layer 430.

In the step S230, in the second undercut structure area UCA2, the portion of the protective layer 700 overlapping with the third hole H2a and the fourth hole H2b may not be etched or may be etched only to a partial thickness.

In the fourth step (S140, S240), a pixel electrode material PEM may be deposited in the first undercut structure area UCA1 and the second undercut structure area UCA2.

In the fifth step (S150, S250), the pixel electrode material PEM may be etched, and the first protrusion 710 may be formed in the first undercut structure area UCA1.

In the sixth step (S260), a bank 440 may be patterned outside the second undercut structure area UCA2. At this time, the protective layer 700 may remain in the second undercut structure area UCA2.

In the seventh step (S270), a photoresist PR may be formed on the overcoat layer 430 located on one side of the third hole H2a and the other side of the fourth hole H2b. The photoresist PR may also be formed on the sides of the overcoat layer 430 located on one side of the third hole H2a and the other side of the fourth hole H2b. This is used for not forming an undercut structure in which the protective layer 700 under the overcoat layer 430 located on one side of the third hole H2a and the other side of the fourth hole H2b is depressed inward in the eighth step (S280). At this time, the protective layer 700 may remain in the second undercut structure area UCA2.

In the eighth step (S280), there may be formed an undercut structure in which the protective layer 700 under the overcoat layer 430 between the third hole H2a and the fourth hole H2b is depressed inward, by wet-etching the protective layer 700 to form (render) the area of the upper surface of the protective layer 700 (corresponding to the second bottom insulating layer 920) under the overcoat layer 430 between the third hole H2a and the fourth hole H2b to be smaller than the area of the rear surface of the overcoat layer 430 between the third hole H2a and the fourth hole H2b. Accordingly, there may be formed the second protrusion 720.

In the fifth step (S150, S250), the pixel electrode material PEM may be removed, and the portion of the first lower metal BM1 overlapping with the first hole H1a and the second hole H1b may be removed. In addition, the portion of the protective layer 700 overlapping with the third hole H2a and the fourth hole H2b may not be etched or may be etched only to a partial thickness.

After the heterogeneous protrusion forming step (S120 to S150, S220 to S280), the deposition process of the inorganic encapsulation layer 460 may be performed.

As a result of deposition of the inorganic encapsulation layer 460, the inorganic encapsulation layer 460 may be broken or disconnected around the first protrusion 710, and may be not broken or disconnected around the second protrusion 720.

The inorganic encapsulation layer 460 may become thinner as it moves away from the display area DA. That is, the farther away from the display area DA, the thinner the inorganic encapsulation layer may become.

Example embodiments of the present disclosure described above are briefly described as follows.

A display device according to example embodiments of the present disclosure may include a substrate, a display area in which a plurality of subpixels are disposed, a non-display area outside the display area, a circuit unit disposed on the substrate and disposed in the non-display area, a protective layer disposed on the circuit unit, an overcoat layer on the protective layer, a common electrode extending from the display area to the non-display area and disposed on the overcoat layer, an inorganic encapsulation layer extending from the display area to the non-display area and disposed on an upper portion and a side of the common electrode, a first protrusion protruding from the substrate, located further outside the common electrode, and having a first eaves, a second protrusion protruding from the substrate, located between the first protrusion and the display area, and having a second eaves, and a first separation inorganic layer disposed on the first protrusion, including the same material as the inorganic encapsulation layer, and separated from the inorganic encapsulation layer.

The inorganic encapsulation layer may be disconnected around the first protrusion, and may be not disconnected around the second protrusion.

A first thickness of the inorganic encapsulation layer around the first protrusion may be smaller than a second thickness of the inorganic encapsulation layer around the second protrusion.

The first protrusion may be located outside the circuit unit, and the second protrusion may be located between the circuit unit and the display area.

The first protrusion may include a first base metal, a first bottom insulating layer located on the first base metal, and including a rear surface of a larger area than an upper surface of the first base metal, and a first top insulating layer on the first bottom insulating layer.

The first eaves may include a portion of the first bottom insulating layer extending further than the first base metal.

The first bottom insulating layer may include the same material as the protective layer and may be separated from the protective layer, and the first top insulating layer may include the same material as the overcoat layer and may be separated from the overcoat layer.

The first protrusion may further include an adhesive functional layer on the first top insulating layer.

The display device according to example embodiments of the present disclosure may further include a base insulating layer between the substrate and the first protrusion, and a first shield metal located between the substrate and the base insulating layer, and overlapping the first protrusion.

A ground voltage may be applied to the first shield metal.

The second protrusion may include a second base metal, a second bottom insulating layer located on the second base metal, a second top insulating layer located on the second bottom insulating layer and having a rear surface of a larger area than an upper surface of the second bottom insulating layer, an organic material layer on the second top insulating layer, and a top metal on the organic material layer.

The second eaves may include a portion of the second top insulating layer extending further than the second bottom insulating layer.

The second bottom insulating layer may include the same material as the protective layer and may be separated from the protective layer, and the second top insulating layer may include the same material as the overcoat layer and may be separated from the overcoat layer.

The display device according to example embodiments of the present disclosure may further include a plurality of pixel electrodes disposed in each of the plurality of subpixels, and an intermediate layer between the plurality of pixel electrodes and the common electrode.

The organic material layer may include an organic material included in the intermediate layer and may be separated from the intermediate layer. The top metal may include the same metal as the common electrode and may be separated from the common electrode.

The display device according to example embodiments of the present disclosure may further include a base insulating layer between the substrate and the second protrusion, and a second shield metal located between the substrate and the base insulating layer, and overlapping with the second protrusion.

A signal output from the circuit unit may be applied to the second shield metal.

The circuit unit may include a gate-in-panel circuit configured to output a scan signal to the plurality of subpixels, a plurality of gate clock lines disposed between the first protrusion and the gate-in-panel circuit, a first gate voltage line disposed between the plurality of gate clock lines and the gate-in-panel circuit, and a second gate voltage line disposed between the gate-in-panel circuit and the second protrusion.

The first eaves may have a larger size than the second eaves.

A method of manufacturing a display device according to example embodiments of the present disclosure may include a base step of forming a first bottom metal on a substrate in a first undercut structure area, forming a second bottom metal on the substrate in a second undercut structure area, forming a protective layer on the first bottom metal and the second bottom metal, and forming an overcoat layer on the protective layer, and a heterogeneous protrusion forming step of forming a first protrusion inside a first trench of the overcoat layer in the first undercut structure area, and forming a second protrusion inside a second trench of the overcoat layer in the second undercut structure area.

The first protrusion may include a first base metal formed by reducing the first lower metal, a first bottom insulating layer located on the first base metal, having a rear surface of a larger area than an upper surface of the first base metal, and including the same material as the protective layer, and a first top insulating layer located on the first bottom insulating layer and including the same material as the overcoat layer.

The second protrusion may include a second base metal corresponding to the second lower metal, a second bottom insulating layer located on the second base metal and including the same material as the protective layer, and a second top insulating layer located on the second bottom insulating layer, having a rear surface of a larger area than an upper surface of the second bottom insulating layer, and including the same material as the overcoat layer.

The substrate may be divided into a display area in which an image is displayed and a non-display area outside the display area. The first undercut structure area and the second undercut structure area may be included in the non-display area, and the first undercut structure area may be located farther from the display area than the second undercut structure area.

The base step is a first step, and the heterogeneous protrusion forming step performed after the first step may include a second step of forming, using a halftone photo mask, a first hole and a second hole in the overcoat layer on the first lower metal, and forming a third groove and a fourth groove in the overcoat layer on the second lower metal, a third step of etching a portion of the protective layer overlapping with the first hole and the second hole by wet-etching the protective layer, and forming a third hole and a fourth hole in the overcoat layer by ashing the overcoat layer to drill the third groove and the fourth groove of the overcoat layer, a fourth step of depositing pixel electrode material, a fifth step of forming the first protrusion by etching the pixel electrode material, a sixth step of removing a portion of the protective layer overlapping with the third and fourth holes, a seventh step of forming a photoresist on the overcoat layer located on one side of the third hole and the other side of the fourth hole, and an eighth step of forming the second protrusion by wet-etching the protective layer to form an area of an upper surface of the protective layer under the overcoat layer between the third hole and the fourth hole to be smaller than an area of a rear surface of the overcoat layer between the third hole and the fourth hole.

In the third step, the portion of the protective layer overlapping with the third hole and the fourth hole may not be etched, or may be etched only to a partial thickness.

In the fifth step, the pixel electrode material may be removed, the portion of the first base metal overlapping with the first hole and the second hole may be removed, and the portion of the protective layer overlapping with the third hole and the fourth hole may not be etched, or may be etched only to a partial thickness.

There may be performed a step of depositing an inorganic encapsulation layer after the heterogeneous protrusion forming step. As a result of the depositing an inorganic encapsulation layer, the inorganic encapsulation layer may be disconnected around the first protrusion, and may be not disconnected around the second protrusion.

The farther away from the display area, the thinner the inorganic encapsulation layer may become.

A display device according to example embodiments of the present disclosure may include a substrate including a display area on which a plurality of subpixels are disposed and a non-display area outside the display area, a circuit unit disposed on the substrate and disposed in the non-display area, a protective layer disposed on the circuit unit, an overcoat layer disposed on the protective layer, a common electrode extending from the display area to the non-display area and disposed on the overcoat layer, an inorganic encapsulation layer extending from the display area to the non-display area and disposed on top of and a side of the common electrode, a first undercut structure area and a second undercut structure area in the non-display area (the first undercut structure area is located farther from the display area than the second undercut structure area), a first protrusion protruding from the substrate in the first undercut structure area, located further outward than the common electrode, and having a first eaves, a second protrusion protruding from the substrate in the second undercut structure area, located between the first protrusion and the display area, and having a second eaves, and a first separation inorganic layer disposed on the first protrusion, including the same material as the inorganic encapsulation layer (or being formed of the same material as the inorganic encapsulation layer), and separated from the inorganic encapsulation layer.

The display device may further comprise a second separation inorganic layer disposed on the outside of the first protrusion, made of the same material as the inorganic encapsulation layer, and separated from the first separation inorganic layer.

The inorganic encapsulation layer may be disconnected around the first protrusion, and may be not disconnected around the second protrusion.

The first protrusion may be located inside a first trench of the material layer including the protective layer and the overcoat layer.

A first thickness of the inorganic encapsulation layer around the first protrusion may be smaller than a second thickness of the inorganic encapsulation layer around the second protrusion.

The second protrusion may be located inside a second trench of the material layer including the protective layer and the overcoat layer.

The first protrusion may be located outside the circuit unit, and the second protrusion may be located between the circuit unit and the display area.

A ground line may be disposed between the first protrusion and the circuit unit, and the inorganic encapsulation layer may extend to the outer side of the ground line.

The first protrusion may include a first base metal, a first bottom insulating layer located on the first base metal, and including a lower surface (or rear surface) with a larger area than an upper surface of the first base metal, and a first top insulating layer on the first bottom insulating layer.

The first eaves may include a portion of the first bottom insulating layer extending further outward than the first base metal.

The first bottom insulating layer may include the same material as the protective layer and may be separated from the protective layer, and the first top insulating layer may include the same material as the overcoat layer and may be separated from the overcoat layer.

The first protrusion may further include an adhesive functional layer on the first top insulating layer.

The adhesive functional layer may be further disposed on the overcoat layer located on the outside of the first protrusion, and/or the adhesive functional layer may be further disposed on the overcoat layer located on the inside of the first protrusion.

The inorganic encapsulation layer may be disconnected or broken by the first eaves of the first protrusion, and in the first undercut structure area, the inorganic encapsulation layer may have a first thickness, the first separation inorganic layer may have a thickness equal to or less than the first thickness, and the second separation inorganic layer may have a thickness equal to or less than the thickness of the first separation inorganic layer.

The display device according to example embodiments of the present disclosure may further include a base insulating layer between the substrate and the first protrusion, and a first shield metal located between the substrate and the base insulating layer, and overlapping the first protrusion.

A ground voltage may be applied to the first shield metal.

The second protrusion may include a second base metal, a second bottom insulating layer located on the second base metal and having a lower surface with a smaller area than an upper surface of the second base metal, a second top insulating layer located on the second bottom insulating layer and having a lower surface (or rear surface) with a larger area than an upper surface of the second bottom insulating layer, an organic material layer located on the second top insulating layer, and a top metal located on the organic material layer.

The second eaves may include a portion of the second top insulating layer extending further outward than the second bottom insulating layer.

The second bottom insulating layer may include the same material as the protective layer and may be separated from the protective layer, and the second top insulating layer may include the same material as the overcoat layer and may be separated from the overcoat layer.

The display device according to example embodiments of the present disclosure may further include a plurality of pixel electrodes disposed in each of the plurality of subpixels, and an intermediate layer between the plurality of pixel electrodes and the common electrode.

The organic material layer may include an organic material included in the intermediate layer and may be separated from the intermediate layer. The top metal may include the same metal as the common electrode and may be separated from the common electrode.

The second eaves may include a portion of the second top insulating layer extending further outward than the second bottom insulating layer, and an organic material layer and a top metal located on the side of the second top insulating layer.

The first eaves may have a first length, and the second eaves may have a total length being equal to the sum of a second length, which is a length of the extended portion of the second top insulating layer extending further outward than the second bottom insulating layer, a thickness of the organic material layer, and a thickness of the top metal, and the first length of the first eaves may be greater than the total length of the second eaves.

The second protrusion may further include a separation capping layer on the top metal.

The display device according to example embodiments of the present disclosure may further include a base insulating layer between the substrate and the second protrusion, and a second shield metal located between the substrate and the base insulating layer, and overlapping with the second protrusion.

A signal output from the circuit unit may be applied to the second shield metal.

The circuit unit may include a gate-in-panel circuit configured to output a scan signal to the plurality of subpixels, a plurality of gate clock lines disposed between the first protrusion and the gate-in-panel circuit, a first gate voltage line disposed between the plurality of gate clock lines and the gate-in-panel circuit, and a second gate voltage line disposed between the gate-in-panel circuit and the second protrusion.

The first eaves may have a larger size than the second eaves.

A method of manufacturing a display device according to example embodiments of the present disclosure may include a base step of forming a first lower metal on a substrate in a first undercut structure area, forming a second lower metal on the substrate in a second undercut structure area, forming a protective layer on the first lower metal and the second lower metal, and forming an overcoat layer on the protective layer, and a heterogeneous protrusion forming step of forming a first protrusion inside a first trench of the overcoat layer in the first undercut structure area, and forming a second protrusion inside a second trench of the overcoat layer in the second undercut structure area.

The first protrusion may include a first base metal formed by reducing the first bottom metal, a first bottom insulating layer located on the first base metal, having a lower surface (or rear surface) with a larger area than an upper surface of the first base metal, and including the same material as the protective layer (or being formed of the same material as the protective layer), and a first top insulating layer located on the first bottom insulating layer and including the same material as the overcoat layer (or being formed of the same material as the overcoat layer).

The second protrusion may include a second base metal corresponding to the second bottom metal, a second bottom insulating layer located on the second base metal and including the same material as the protective layer (or being formed of the same material as the protective layer), and a second top insulating layer located on the second bottom insulating layer, having a lower surface (or rear surface) with a larger area than an upper surface of the second bottom insulating layer, and including the same material as the overcoat layer (or being formed of the same material as the overcoat layer).

The substrate may be divided into a display area in which an image is displayed and a non-display area outside the display area. The first undercut structure area and the second undercut structure area may be included in the non-display area, and the first undercut structure area may be located farther from the display area than the second undercut structure area.

The base step is a first step, and the heterogeneous protrusion forming step performed after the first step may include a second step of forming, using a halftone photo mask, a first hole and a second hole in the overcoat layer on the first bottom metal, and forming a third groove and a fourth groove in the overcoat layer on the second bottom metal, a third step of etching a portion of the protective layer overlapping with the first hole and the second hole by wet-etching the protective layer, and ashing the overcoat layer to penetrate through (or drill through) the third groove and the fourth groove of the overcoat layer, so as to form a third hole and a fourth hole in the overcoat layer, a fourth step of depositing pixel electrode material, a fifth step of forming the first protrusion by etching the pixel electrode material, a sixth step of removing a portion of the protective layer overlapping with the third and fourth holes, a seventh step of forming a photoresist on the overcoat layer located on one side of the third hole and the other side of the fourth hole, and an eighth step of forming the second protrusion by wet-etching the protective layer to render an area of an upper surface of the protective layer under the overcoat layer between the third hole and the fourth hole to be smaller than an area of a lower surface (or rear surface) of the overcoat layer between the third hole and the fourth hole.

In the third step, the portion of the protective layer overlapping with the third hole and the fourth hole may not be etched, or may be etched only to a partial thickness.

In the fifth step, the pixel electrode material may be removed, the portion of the first base metal overlapping with the first hole and the second hole may be removed, and the portion of the protective layer overlapping with the third hole and the fourth hole may not be etched, or may be etched only to a partial thickness.

There may be performed a step of depositing an inorganic encapsulation layer after the heterogeneous protrusion forming step. As a result of the depositing an inorganic encapsulation layer, the inorganic encapsulation layer may be disconnected around the first protrusion, and may be not disconnected around the second protrusion.

The inorganic encapsulation layer may be formed so that the farther away from the display area, the thinner the inorganic encapsulation layer may become.

According to the example embodiments of the present disclosure described above, it is possible to provide a display device having a structure of narrow bezel and robust reliability, and a method of manufacturing the same.

According to example embodiments of the present disclosure, it is possible to provide a display device with a structure advantageous for implementing the narrow bezel, and a method of manufacturing the same.

According to example embodiments of the present disclosure, it is possible to provide a display device with a structure capable of preventing cracks from spreading in an encapsulation layer within the display panel, and a method of manufacturing the same.

According to example embodiments of the present disclosure, it is possible to provide a display device with a structure capable of preventing a penetration of external substances such as moisture or oxygen, and a method of manufacturing the same.

According to example embodiments of the present disclosure, it is possible to provide a display device with a structure capable of preventing the external substances introduced inside from diffusing into a display area, and a method of manufacturing the same.

According to example embodiments of the present disclosure, it is possible to provide a display device with a structure capable of preventing image abnormalities caused by external substances introduced inside, and a method of manufacturing the same.

According to the embodiments of the present disclosure described above, it is possible to provide a display device having a structure for narrow bezel and reliability robustness, and a method of manufacturing the same.

According to example embodiments of the present disclosure, it is possible to provide a display device with a structure advantageous for implementing the narrow bezel, and a method of manufacturing the same.

According to example embodiments of the present disclosure, it is possible to provide a display device with a structure capable of preventing cracks from spreading in an encapsulation layer within the display panel, and a method of manufacturing the same.

According to example embodiments of the present disclosure, it is possible to provide a display device with a structure capable of preventing a penetration of external substances such as moisture or oxygen, and a method of manufacturing the same.

According to example embodiments of the present disclosure, it is possible to provide a display device with a structure capable of preventing the external substances introduced inside from diffusing into a display area, and a method of manufacturing the same.

According to example embodiments of the present disclosure, it is possible to provide a display device with a structure capable of preventing image abnormalities caused by external substances introduced inside, and a method of manufacturing the same.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown. The scope of protection of the present disclosure should be construed based on the following claims, and all technical features within the scope of equivalents thereof should be construed as being included within the scope of the present disclosure.

What is claimed is:

1. A display device, comprising:
a substrate;
a display area in which a plurality of subpixels are disposed;
a non-display area outside the display area;
a circuit unit disposed on the substrate and disposed in the non-display area;
a protective layer disposed on the circuit unit;
an overcoat layer on the protective layer;
a common electrode extending from the display area to the non-display area and disposed on the overcoat layer;
an inorganic encapsulation layer extending from the display area to the non-display area and disposed on an upper portion and a side of the common electrode;
a first protrusion protruding from the substrate, located further outside the common electrode, and having a first eaves;
a second protrusion protruding from the substrate, located between the first protrusion and the display area, and having a second eaves; and
a first separation inorganic layer disposed on the first protrusion, including a same material as the inorganic encapsulation layer, and separated from the inorganic encapsulation layer.

2. The display device of claim 1, wherein the inorganic encapsulation layer is disconnected around the first protrusion, and is not disconnected around the second protrusion.

3. The display device of claim 1, wherein a first thickness of the inorganic encapsulation layer around the first protrusion is smaller than a second thickness of the inorganic encapsulation layer around the second protrusion.

4. The display device of claim 1, wherein the first protrusion is located outside the circuit unit, and the second protrusion is located between the circuit unit and the display area.

5. The display device of claim 1, wherein the first protrusion includes:
a first base metal;
a first bottom insulating layer located on the first base metal, and including a rear surface of a larger area than an upper surface of the first base metal; and
a first top insulating layer on the first bottom insulating layer,
wherein the first eaves includes a portion of the first bottom insulating layer extending further outward than the first base metal.

6. The display device of claim 5, wherein the first bottom insulating layer includes a same material as the protective layer and is separated from the protective layer,
wherein the first top insulating layer includes a same material as the overcoat layer and is separated from the overcoat layer.

7. The display device of claim 5, wherein the first protrusion further includes an adhesive functional layer on the first top insulating layer.

8. The display device of claim 5, further comprising:
a base insulating layer between the substrate and the first protrusion; and
a first shield metal located between the substrate and the base insulating layer, and overlapping the first protrusion.

9. The display device of claim 8, wherein a ground voltage is for being applied to the first shield metal.

10. The display device of claim 1, wherein the second protrusion includes:
a second base metal;
a second bottom insulating layer located on the second base metal;
a second top insulating layer located on the second bottom insulating layer and having a rear surface of a larger area than an upper surface of the second bottom insulating layer;
an organic material layer on the second top insulating layer; and
a top metal on the organic material layer,
wherein the second eaves includes a portion of the second top insulating layer extending further than the second bottom insulating layer.

11. The display device of claim 10, wherein the second bottom insulating layer includes a same material as the protective layer and is separated from the protective layer,
wherein the second top insulating layer includes a same material as the overcoat layer and is separated from the overcoat layer.

12. The display device of claim 10, further comprising:
a plurality of pixel electrodes disposed in each of the plurality of subpixels; and
an intermediate layer between the plurality of pixel electrodes and the common electrode,
wherein the organic material layer includes an organic material included in the intermediate layer and is separated from the intermediate layer, and
wherein the top metal includes a same metal as the common electrode and is separated from the common electrode.

13. The display device of claim 10, further comprising:
a base insulating layer between the substrate and the second protrusion; and
a second shield metal located between the substrate and the base insulating layer, and overlapping with the second protrusion.

14. The display device of claim 13, wherein a signal output from the circuit unit is for being applied to the second shield metal.

15. The display device of claim 1, wherein the circuit unit includes:
a gate-in-panel circuit configured to output a scan signal to the plurality of subpixels;
a plurality of gate clock lines disposed between the first protrusion and the gate-in-panel circuit;
a first gate voltage line disposed between the plurality of gate clock lines and the gate-in-panel circuit; and
a second gate voltage line disposed between the gate-in-panel circuit and the second protrusion.

16. The display device of claim 1, wherein the first eaves has a larger size than the second eaves.

17. A method of manufacturing a display device, comprising:
forming a first bottom metal on a substrate in a first undercut structure area, forming a second bottom metal on the substrate in a second undercut structure area, forming a protective layer on the first bottom metal and the second bottom metal, and forming an overcoat layer on the protective layer; and
forming a first protrusion inside a first trench of the overcoat layer in the first undercut structure area, and forming a second protrusion inside a second trench of the overcoat layer in the second undercut structure area,
wherein the first protrusion includes:
a first base metal formed by reducing a first lower metal;
a first bottom insulating layer located on the first base metal, having a rear surface of a larger area than an upper surface of the first base metal, and including a same material as the protective layer; and
a first top insulating layer located on the first bottom insulating layer and including a same material as the overcoat layer,
wherein the second protrusion includes:
a second base metal corresponding to a second lower metal;
a second bottom insulating layer located on the second base metal and including the same material as the protective layer; and
a second top insulating layer located on the second bottom insulating layer, having a rear surface of a larger area than an upper surface of the second bottom insulating layer, and including the same material as the overcoat layer,
wherein the substrate is divided into a display area in which an image is to be displayed and a non-display area outside the display area, and
wherein the first undercut structure area and the second undercut structure area are included in the non-display area, and the first undercut structure area is located farther from the display area than the second undercut structure area.

18. The method of claim 17, wherein the forming the first and second protrusions comprises:
forming, using a halftone photo mask, a first hole and a second hole in the overcoat layer on the first lower metal, and forming a third groove and a fourth groove in the overcoat layer on the second lower metal;
etching a portion of the protective layer overlapping with the first hole and the second hole by wet-etching the protective layer, and forming a third hole and a fourth hole in the overcoat layer by ashing the overcoat layer to drill the third groove and the fourth groove of the overcoat layer;
depositing pixel electrode material;
forming the first protrusion by etching the pixel electrode material;
forming a photoresist on the overcoat layer located on one side of the third hole and another side of the fourth hole; and
forming the second protrusion by wet-etching the protective layer to form an area of an upper surface of the protective layer under the overcoat layer between the third hole and the fourth hole to be smaller than an area of a rear surface of the overcoat layer between the third hole and the fourth hole.

19. The method of claim 17, further comprising depositing an inorganic encapsulation layer performed after the forming the first and second protrusions,
wherein, as a result of the depositing an inorganic encapsulation layer, the inorganic encapsulation layer is disconnected around the first protrusion, and is not disconnected around the second protrusion.

20. The method of claim 19, wherein the farther away from the display area, the thinner the inorganic encapsulation layer becomes.
